(19) United States
(12) Patent Application Publication
(10) Pub. No.: US 2015/0357427 A1
(43) Pub. Date: Dec. 10, 2015

(54) Integrated Circuit Device with Metal Gates Including Diffusion Barrier Layers and Fabricating Methods Thereof

(71) Applicants: Ju-Youn Kim, Suwon-si (KR); Tae-Won Ha, Seongnam-si (KR)

(72) Inventors: Ju-Youn Kim, Suwon-si (KR); Tae-Won Ha, Seongnam-si (KR)

(21) Appl. No.: 14/830,863

(22) Filed: Aug. 20, 2015

Related U.S. Application Data
(62) Division of application No. 13/833,750, filed on Mar. 15, 2013.

(30) Foreign Application Priority Data
Jun. 27, 2012 (KR) 10-2012-0069247

(51) Int. Cl. H01L 29/423; H01L 29/51; H01L 29/78; H01L 29/49

(52) U.S. Cl. CPC H01L 29/42372; H01L 29/495; H01L 29/518; H01L 29/511; H01L 29/78

(57) ABSTRACT

An integrated circuit device with metal gates including diffusion barrier layers and fabricating methods thereof are provided. The device may include a gate insulating film, a first conductivity type work function regulating film on the gate insulating film and a metal gate pattern on the first conductivity type work function regulating film. The device may include a cobalt film between the gate insulating film and the metal gate pattern to reduce diffusion from the metal gate pattern into the gate insulating film.

### CROSS-REFERENCE TO RELATED APPLICATION

This is a divisional of U.S. patent application Ser. No. 13/833,750, filed Mar. 15, 2013, which is a U.S. non-provisional application claiming priority under 35 U.S.C. §119 to Korean Patent Application No. 10-2012-0069247, filed Jun. 27, 2012, in the Korean Intellectual Property Office, the disclosures of which are hereby incorporated herein by reference in their entireties.

### FIELD

The present disclosure generally relates to the field of electronics, and particularly semiconductor devices.

### BACKGROUND

High-k gate dielectric films may be used to reduce leakage current between the gate electrodes and the channel regions with relatively thin equivalent oxide thickness. Metal gate electrodes may be used to reduce resistance of the gates. Accordingly, transistors including high-k gate dielectric films and metal gate electrodes have been used to improve performance of high density integrated circuit devices.

### SUMMARY

A semiconductor device may include an interlayer dielectric film including a trench on a substrate and a gate insulating film in the trench. The device may further include a first work function regulating film on the gate insulating film in the trench, a second work function regulating film on the first work function regulating film in the trench and a cobalt film between the first and second work function regulating films.

In some embodiments, the first work function regulating film may include a P-type work function regulating film and the second work function regulating film may include an N-type work function regulating film.

In some embodiments, the first work function regulating film may include a TiN film and the second work function regulating film may include a TiAl film.

According to some embodiments, the device may also include a metal gate pattern on the second work function regulating film to fill the trench.

According to some embodiments, the device may also include an adhesive film between the second work function regulating film and the metal gate pattern.

In some embodiments, thicknesses of the first and second work function regulating films, the cobalt film and the adhesive film may be constant along sidewalls and a bottom surface of the trench.

In some embodiments, the cobalt film may have a thickness in a range of about 5 Å to about 50 Å.

According to some embodiments, the device may also include an etch stopper film between the gate insulating film and the first work function regulating film in the trench.

In some embodiments, the semiconductor device may be a fin-type transistor.

According to some embodiments, the gate insulating film may include a high-k dielectric film and a thickness of the gate insulating film may be constant along sidewalls and bottom surface of the trench.

A transistor of a first conductivity type may include an interlayer dielectric film including a trench on a substrate, a gate insulating film on sidewalls and bottom surface of the trench. The transistor may further include a work function regulating film of the first conductivity type on the gate insulating film, a metal gate pattern on the work function regulating film filling the trench and a cobalt film between the gate insulating film and the metal gate pattern.

In some embodiments, the first conductivity type may be P-type.

In some embodiments, the transistor may also include an N-type work function regulating film between the work function regulating film and the metal gate pattern. The cobalt film may be between the work function regulating film and the N-type work function regulating film.

According to some embodiments, the transistor may also include an etch stopper film between the gate insulating film and the work function regulating film. The cobalt film may be between the etch stopper film and the work function regulating film.

In some embodiments, the transistor may also include an etch stopper film including a TiN film and a TaN film sequentially stacked between the gate insulating film and the work function regulating film. The cobalt film may be between the TiN film and the TaN film.

According to some embodiments, the first conductivity type may be N-type.

In some embodiments, the cobalt film may gave a thickness in range of about 5 Å to about 50 Å.

A semiconductor device may include an interlayer dielectric film including a trench on a substrate and a gate insulating film in the trench. The device may further include a TiN film on the gate insulating film in the trench, an Al film on the TiN film in the trench and a cobalt film between the TiN film and the Al film in the trench.

In some embodiments, the device may also include a TaN film between the TiN film and the cobalt film. Moreover, the device may also include a TiAl film between the cobalt film and the Al film in the trench.

A semiconductor device may include a substrate including a first region and a second region and an N-type transistor on the first region including a first replacement metal gate, which may include a first gate insulating film on the substrate, an N-type work function regulating film on the first gate insulating film, a first metal gate pattern on the N-type work function regulating film, and a first cobalt film between the first gate insulating film and the first metal gate pattern. The device may further include a P-type transistor on the second region including a second replacement metal gate, which may include a second gate insulating film on the substrate, a P-type work function regulating film on the second gate insulating film, a second metal gate pattern on the P-type work function regulating film, and a second cobalt film between the second gate insulating film and the second metal gate pattern.

In some embodiments, the first replacement metal gate may be free of the P-type work function regulating film.

In some embodiments, the second replacement metal gate may be free of the N-type work function regulating film.

According to some embodiments, the second replacement metal gate further may include the N-type work function regulating film on the second cobalt film.

An integrated circuit device including a first transistor of a first conductivity type, the first transistor may include a first gate insulating layer on a substrate, a work function regulating layer of the first conductivity type on the first gate insulating layer and a first metal gate layer on the work function regulating layer. The device may further include a first diffusion barrier layer between the first gate insulating layer and the first metal gate layer.

In some embodiments, the first diffusion barrier layer may include a cobalt film.

In some embodiments, the first transistor further may include a TiN film between the first gate insulation layer and the first diffusion barrier layer.

According to some embodiments, the first transistor further may include a TaN film between the TiN film and the first diffusion barrier layer.

In some embodiments, the first metal gate layer may include an aluminum film and the first transistor further may include a TiAl film between the first diffusion barrier layer and the first metal gate layer.

In some embodiments, the work function regulating layer of the first conductivity type may include a first work function regulating layer and the first transistor further may include a second work function regulating layer of a second conductivity type on the first work function regulating layer. The first diffusion barrier layer may include a cobalt film. The first diffusion barrier layer may be between the first and second work function regulating layers.

In some embodiments, the work function regulating layer of the first conductivity type may include a first work function regulating layer and the integrated circuit device further include a second transistor of a second conductivity type, which may include a second gate insulating layer on the substrate, a second work function regulating layer of the second conductivity type on the second gate insulating layer, a second metal gate layer on the second work function regulating layer and a second diffusion barrier layer between the second gate insulating layer and the second metal gate layer. The second transistor is free of the first work function regulating layer.

In some embodiments, the first and second diffusion barrier layers may include a cobalt film.

According to some embodiments, the first transistor further may include the second work function regulating layer on the first work function regulating layer and the first diffusion barrier layer may be between the first and second work function regulating layers. The first transistor further may include a TiN film between the first gate insulation layer and the first diffusion barrier layer and the metal gate pattern may include an aluminum film.

### BRIEF DESCRIPTION OF THE DRAWINGS

FIG. 1 through 8 are cross-sectional views of a semiconductor device according to some embodiments of the present inventive concept;

FIG. 9A and FIG. 9B are cross-sectional views taken along the line A-A′ and B-B′ of FIG. 8 respectively;

FIG. 10 is a circuit diagram of a semiconductor device according to some embodiments of the present inventive concept;

FIG. 11 is a layout view of a semiconductor device according to some embodiments of the present inventive concept;

FIG. 12 illustrate a semiconductor device according to some embodiments embodiment of the present inventive concept;

FIG. 13 is a block diagram of an electronic system incorporating a semiconductor device according to some embodiments of the present inventive concept;

FIGS. 14A and 14B illustrate exemplary electronic systems including a semiconductor device according to some embodiments of the present inventive concept; and

FIGS. 15 through 21 illustrate intermediate process steps for explaining the manufacturing method of a semiconductor device according to some embodiments of the present inventive concept.

### DETAILED DESCRIPTION

Example embodiments are described below with reference to the accompanying drawings. Many different forms and embodiments are possible without deviating from the spirit and teachings of this disclosure and so the disclosure should not be construed as limited to the example embodiments set forth herein. Rather, these example embodiments are provided so that this disclosure will be thorough and complete, and will convey the scope of the disclosure to those skilled in the art. In the drawings, the sizes and relative sizes of layers and regions may be exaggerated for clarity. Like reference numbers refer to like elements throughout.

Example embodiments of the inventive concepts are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, example embodiments of the inventive concepts should not be construed as limited to the particular shapes illustrated herein but include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, integers, steps, operations, elements, and/or components, but do not preclude the presence or addition of one or more other features, integers, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein the term “and/or” includes any and all combinations of one or more of the associated listed items.

It will be understood that although the terms first, second, etc. may be used herein to describe various elements, these elements should not be limited by these terms. These terms are only used to distinguish one element from another. Thus, a first element could be termed a second element without departing from the teachings of the present embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein may be interpreted accordingly.

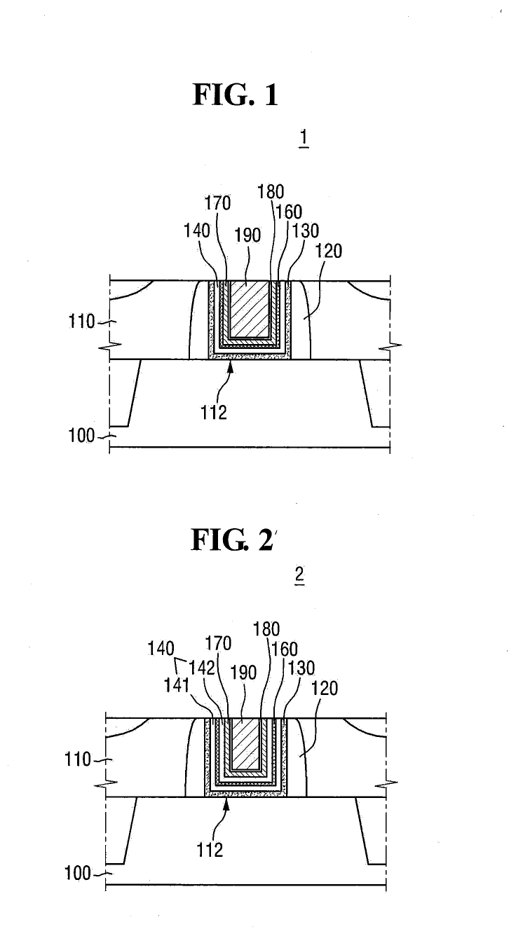

FIG. 1 is a cross-sectional view of a semiconductor device according to some embodiments of the present inventive concept. In FIG. 1, a gate of an NMOS transistor is illustrated as an example, but aspects of the present inventive concept are not limited thereto.

The semiconductor device 1 may include a substrate 100, a first interlayer dielectric film 110 having a first trench 112, a first gate insulating film 130, a first etch stopper film 140, a first cobalt film 160, an N-type work function regulating film 170, a first adhesive film 180, and a first metal gate pattern 190.

The active region is defined by forming an isolation film, such as a shallow trench isolation (STI) film, in the substrate 100. The substrate 100 may be made of at least one semiconductor material selected from the group consisting of Si, Ge, SiGe, GaP, GaAs, SiC, SiGeC, InAs and InP. In addition, a silicon on insulator (SOI) substrate may be used.

The first interlayer dielectric film 110 is formed on the substrate 100 and may include the first trench 112. The first interlayer dielectric film 110 may be formed by stacking two or more insulation films. As shown, a spacer 120 may be formed on the sidewalls of the first trench 112 and the substrate 100 may be disposed on the bottom surface of the trench 112, but aspects of the present inventive concept are not limited thereto. The spacer 120 may include at least one of a nitride film and an oxynitride film.

The first gate insulating film 130 may be conformally formed along the sidewalls and bottom surface of the first trench 112. The first gate insulating film 130 may include a high dielectric constant material having a higher dielectric constant than a silicon oxide film. For example, the first gate insulating film 130 may include a material selected from the group consisting of HfO2, ZrO2, Ta2O5, TiO2, SrTiO3 and (Ba,Sr)TiO3. The first gate insulating film 130 may be formed to have an appropriate thickness according to the type of device to be formed. For example, when the first gate insulating film 130 is a HfO2 film, it may have a thickness of about 50 Å or less, for example in range of about 5 to about 50 Å.

The first etch stopper film 140 may be formed on the first gate insulating film 130 in the first trench 112. As shown in FIG. 1, the first etch stopper film 140 may be conformally formed along sidewalls and bottom surface of the first trench 112. The first etch stopper film 140 may include, for example, at least one of TiN and TaN. In addition, the first etch stopper film 140 may include a TiN film and a TaN film sequentially stacked. Here, the first etch stopper film 140 may be used as an etch stopper during etching the N-type work function regulating film 170. The first etch stopper film 140 may be formed to have an appropriate thickness according to the type of device to be formed. For example, when the first etch stopper film 140 is a TiN film, it may have a thickness in range of about 5 to about 40 Å. When the first etch stopper film 140 is a TaN film, it may have a thickness in range of about 5 to about 30 Å.

The first cobalt film 160 may be formed on the first etch stopper film 140 in the first trench 112. As shown, the first cobalt film 160 may be conformally formed along sidewalls and bottom surface of the first trench 112.

The N-type work function regulating film 170 may be formed in the first trench 112 on the first cobalt film 160. As shown, the N-type work function regulating film 170 may also be conformally formed along sidewalls and bottom surface of the first trench 112. The N-type work function regulating film 170 regulates operating characteristics of an N-type transistor by adjusting the work function of the N-type transistor. The N-type work function regulating film 170 may be made of a material selected from the group consisting of TiAl, TiAlN, TaC, TiC, and HfSi. For example, the N-type work function regulating film 170 may be a TiAl film. For example, the N-type work function regulating film 170 may have a thickness in range of about 30 Å to about 120 Å.

The first adhesive film 180 may be formed on the N-type work function regulating film 170 in the first trench 112. As shown, the first adhesive film 180 may also be conformally formed along sidewalls and bottom surface of the first trench 112. The first adhesive film 180 may include at least one of TiN and Ti. In addition, the first adhesive film 180 may include a TiN film and a Ti film sequentially stacked. For example, the TiN film may have a thickness in range of about 5 Å and 100 Å and the Ti film may have a thickness in range of about 5 Å to about 100 Å. The first adhesive film 180 may increase adhesiveness of the first metal gate pattern 190 to be formed later.

The first metal gate pattern 190 may be formed on the first adhesive film 180 of the first trench 112 to fill the first trench 112. The first metal gate pattern 190 may include aluminum (Al) or tungsten (W), but aspects of the present inventive concept are not limited thereto.

The semiconductor device 1 according to some embodiments of the present inventive concept, the first cobalt film 160 may be disposed under the first metal gate pattern 190. For example, the first cobalt film 160 may be disposed under the N-type work function regulating film 170 in the first trench 112.

The first cobalt film 160 may reduce diffusion of a material (e.g., Al) included in the first metal gate pattern 190 into the first gate insulating film 130. As appreciated by the present inventors, diffusion of a material included in the metal gate pattern (e.g., Al) into the first gate insulating film 130 may cause leakage current. According to some embodiments, if the material included in the metal gate pattern (e.g., Al) is diffused, the first cobalt film 160 may react with the material. Therefore, the material included in the metal gate pattern (e.g., Al) may not be diffused into the first gate insulating film 130. The first cobalt film 160 may also reduce diffusion of a material (e.g., F) used during forming the first metal gate pattern 190 into the first gate insulating film 130. That is, the first cobalt film 160 may also function as a diffusion barrier layer.

In addition, when the first adhesive film 180 is formed, overhang may be generated. The generation of overhang may be reduced by forming the first cobalt film 160.

The first cobalt film 160 may be formed to have a thickness in range of, for example, about 5 to about 50 Å. The first cobalt film 160 having a thickness less than 5 Å may not reduce diffusion of the materials from the metal gate pattern 190 into the first gate insulating film 130. The first cobalt film 160 having a thickness greater than 50 Å will make manufacturing process difficult since various material layers including the first cobalt film 160 may be formed in the first trench 112.

The first cobalt film 160 may be formed by such as, for example, chemical vapor deposition (CVD) or atomic layer deposition (ALD to conformally form the cobalt film 160 having an appropriate thickness.

FIG. 2 is a cross-sectional view of a semiconductor device according to some embodiments of the present inventive concept.

The semiconductor device 2 may include a first etch stopper film 140 having a multi-layered structure including two or more films. The first etch stopper film 140 may include a first film 141 (for example, a TiN film) and a second film 242 (for example, a TaN film).

A first cobalt film 160 may be under the first metal gate pattern 190. The first cobalt film 160 may reduce diffusion of a material (e.g., Al) in the first metal gate pattern 190 into the first gate insulating film 130.

The first cobalt film 160 may be within the first etch stopper film 140 having a stacked structure of multiple layers 141 and 142. For example, the first cobalt film 160 may be between the first film 141 and the second film 142. Since the first cobalt film 160 is between the first gate insulating film 130 and the first metal gate pattern 19Q, it may reduce diffusion of a material (e.g., Al) in the first metal gate pattern 190 into the first gate insulating film 130.

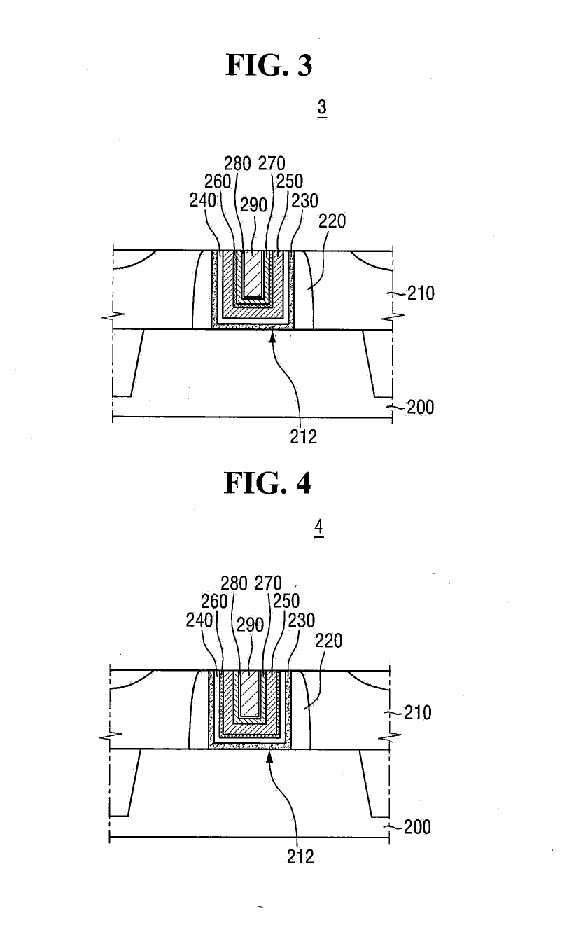

FIG. 3 is a cross-sectional view of a semiconductor device according to some embodiments of the present inventive concept.

In FIG. 3, a gate of a PMOS transistor is illustrated as an example, but aspects of the present inventive concept are not limited thereto.

The semiconductor device 3 may include a substrate 200, a second interlayer dielectric film 210 including a second trench 212, a second gate insulating film 230, a second etch stopper film 240, a P-type work function regulating film 250, a second cobalt film 260, an N-type work function regulating film 270, a second adhesive film 280, and a second metal gate pattern 290.

The second interlayer dielectric film 210 may be formed on the substrate 100 and may include a second trench 212.

The second gate insulating film 230 may be conformally formed along the sidewalls and bottom surface of the second trench 212. The second gate insulating film 230 may include a material selected from the group consisting of HfO2, ZrO2, Ta2O5, TiO2, SrTiO3 and (Ba,Sr)TiO3.

The second etch stopper film 240 may be formed on the second gate insulating film 230 in the second trench 212. The second etch stopper film 240 may include, for example, at least one of TiN and TaN. In some embodiments, the second etch stopper film 240 may include a TiN film and a TaN film sequentially stacked.

The P-type work function regulating film 250 may be formed on the second etch stopper film 240 in the second trench 212. As shown, the P-type work function regulating film 250 may also be conformally formed along sidewalls and bottom surface of the second trench 212. The P-type work function regulating film 250 regulates operating characteristics of a P-type transistor by adjusting the work function of the P-type transistor. For example, the P-type work function regulating film 250 may be a TiAl film. For example, the P-type work function regulating film 250 may have a thickness in range of about 50 Å to about 100 Å.

The second cobalt film 260 may be formed on the second etch stopper film 240 in the second trench 212. As shown, the second cobalt film 260 may be conformally formed along sidewalls and bottom surface of the second trench 212.

The N-type work function regulating film 270 may be formed on the second cobalt film 260 in the second trench 212. As shown, the N-type work function regulating film 270 may also be conformally formed along sidewalls and bottom surface of the second trench 212. As illustrated, the N-type work function regulating film 270 may be in the P-type transistor to reduce the number of photolithography processes.

The second adhesive film 280 may be formed on the N-type work function regulating film 270 in the second trench 212.

The second metal gate pattern 290 may be formed on the second adhesive film 280 in the second trench 212 to fill the second trench 212. The second metal gate pattern 290 may include aluminum (Al) or tungsten (W), but aspects of the present inventive concept are not limited thereto.

The second cobalt film 260 may reduce diffusion of a material (e.g., Al) in the second metal gate pattern 290 into the second gate insulating film 230. Forming the second cobalt film 260 may reduce overhang generated during forming the second adhesive film 280.

FIG. 4 is a cross-sectional view of a semiconductor device according to some embodiments of the present inventive concept.

The semiconductor device 4 may include a second cobalt film 260 under a P-type work function regulating film 250. The second cobalt film 260 may be between the P-type work function regulating film 250 and a second etch stopper film 240.

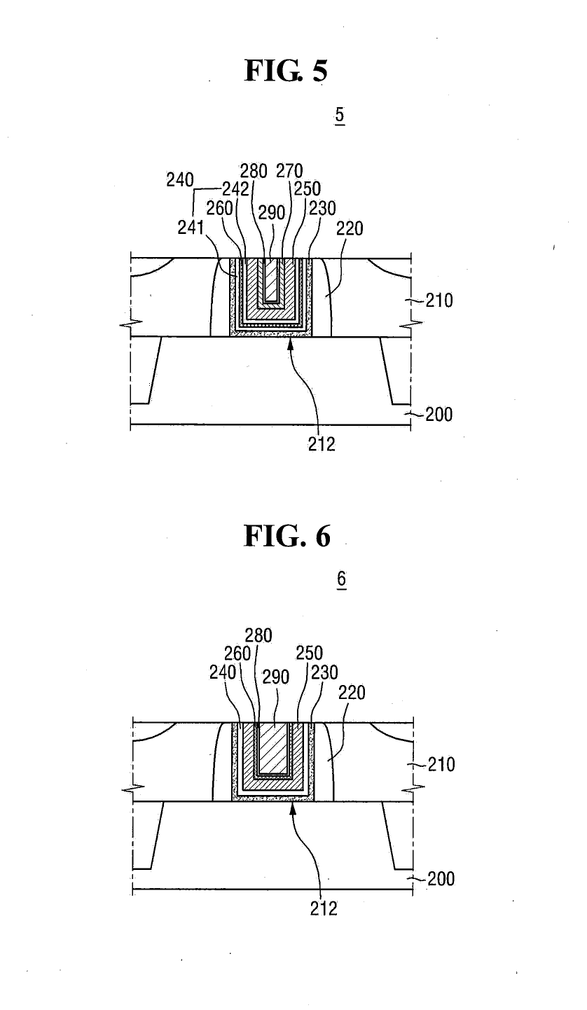

FIG. 5 is a cross-sectional view of a semiconductor device according to some embodiments of the present inventive concept.

The semiconductor device 5 may include a second etch stopper film 240 formed to have a multi-layered structure having two or more films stacked. As shown, the second etch stopper film 240 may include a third film 241 (for example, a TiN film) and a fourth film 242 (for example, a TaN film).

A second cobalt film 260 may be under the second metal gate pattern 290. The second cobalt film 260 may reduce diffusion of a material (e.g., Al) in the second metal gate pattern 290 into the second gate insulating film 230.

The second cobalt film 260 may be within the second etch stopper film 240 having a stacked structure of multiple layers 241 and 242. For example, the second cobalt film 260 may be between the third film 241 and the fourth film 242. Since the second cobalt film 260 is still between the second gate insulating film 230 and the second metal gate pattern 290, it may reduce diffusion of a material (e.g., Al) in the second metal gate pattern 290 into the second gate insulating film 230

FIG. 6 is a cross-sectional view of a semiconductor device according to some embodiments of the present inventive concept.

The semiconductor device 6 may be free of an N-type work function regulating film to maximize the operating characteristics of a P-type transistor, the N-type work function regulating film 270 may be removed.

In this case, the second cobalt film 260 may be between the P-type work function regulating film 250 and the second adhesive film 280.

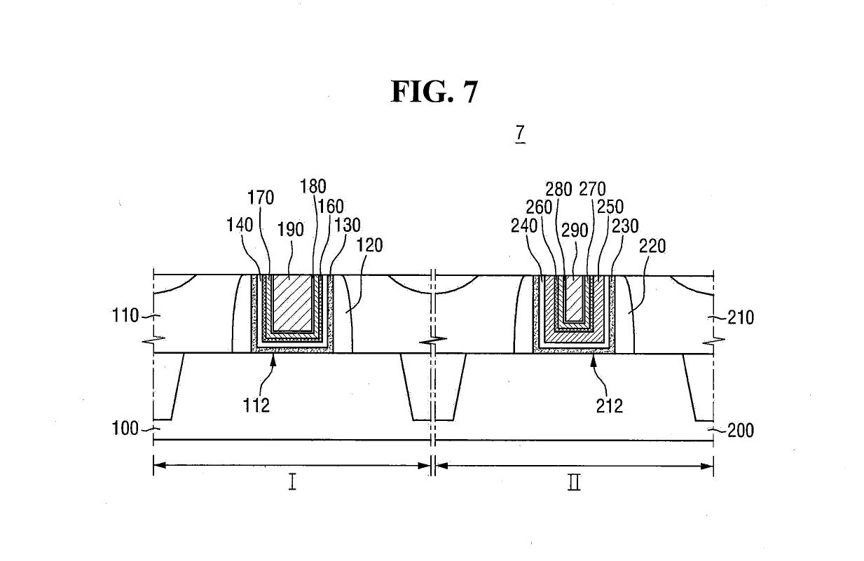

FIG. 7 is a cross-sectional view of a semiconductor device according to some embodiments of the present inventive concept.

The semiconductor device 7 may include a first region I and a second region II in a substrate 100, an N-type transistor in the first region I and a P-type transistor in the second region II.

In addition, the N-type transistor may include a first replacement metal gate such as, for example, illustrated in FIG. 1. The P-type transistor may include a second replacement metal gate such as, for example, illustrated in FIG. 3.

The first replacement metal gate may include an N-type work function regulating film 170 and a first cobalt film 160 disposed under the N-type work function regulating film 170. In addition, the first replacement metal gate may not include a P-type work function regulating film.

The second replacement metal gate may include a second cobalt film 260 disposed between the P-type work function regulating film 250 and the N-type work function regulating film 270.

For example, the N-type work function regulating films 170 and 270 may be TiAl films and the P-type work function regulating film 250 may be a TiN film.

In some embodiments, one of the two N-type transistor gates (shown in FIGS. 1 and 2) and one of the four P-type transistor gates shown in FIGS. 1, 2, 3 and 4) may be formed on a substrate. For example, the N-type transistor gate in FIG. 1 may be formed in the first region I and the P-type transistor gate shown in FIG. 6 may be formed in the second region II.

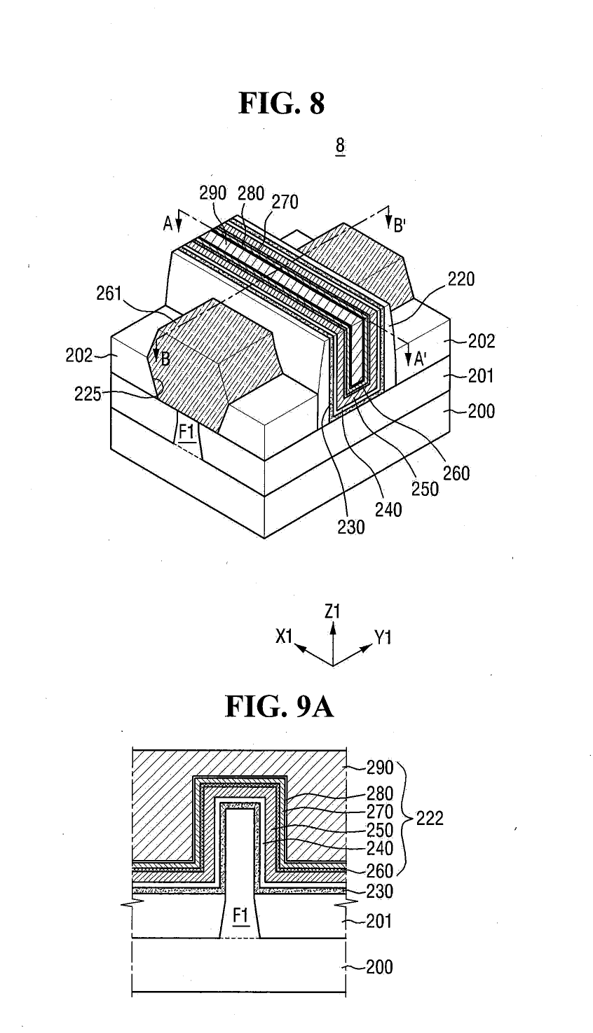

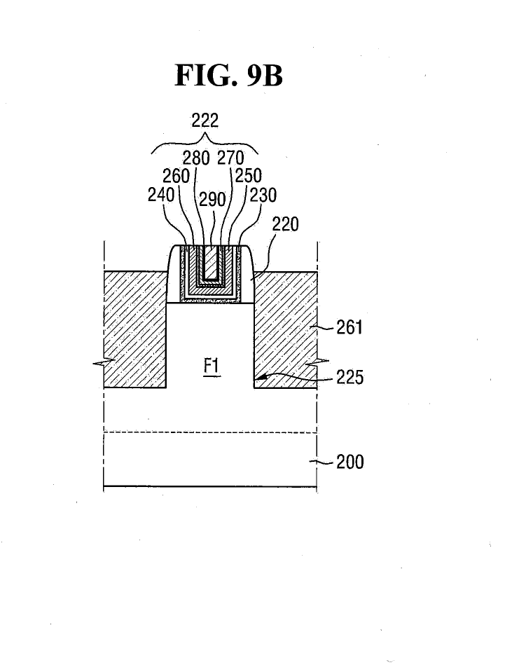

FIG. 8 is a perspective view of a semiconductor device according to some embodiments of the present inventive concept. FIG. 9A and FIG. 9B are cross-sectional views taken along the line A-A′ and B-B′ of FIG. 8 respectively. In FIGS. 8, 9A and 9B, the gate of the P-type transistor illustrated in FIG. 3 is applied to a fin-type transistor FinFET.

The semiconductor device 8 may include a fin F1, a gate electrode 222, a recess 225, and a source/drain 261.

The fin F1 may extend in a second direction Y1. The fin F1 may be a portion of a substrate 200 and may include an epitaxial layer grown from the substrate 200. An isolation film 201 may cover sidewalls of the fin F1.

The gate electrode 222 may be formed on the fin F1 to cross over the fin F1. The gate electrode 222 may extended in a first direction X1, which is perpendicular to the second direction Y1

The gate electrode 222 may include a second gate insulating film 230, a second etch stopper film 240, a P-type work function regulating film 250, a second cobalt film 260, an N-type work function regulating film 270, a second adhesive film 280, and a second metal gate pattern 290.

The recess 225 may be formed on the fin F1 at both sides of the gate electrode 222. Since sidewalls of the recess 225 are inclined, the recess 225 may be shaped such that it becomes wider away from the substrate 100. As shown in FIG. 8, a width of the recess 225 may be greater than that of the fin F1.

The source/drain 261 may be formed in the recess 225. The source/drain 261 may be an elevated source/drain. That is to say, a top surface of the source/drain 261 may be higher than a bottom surface of an interlayer dielectric film 201. In addition, the source/drain 261 and the gate electrode 222 may be insulated from each other by a spacer 220.

When the semiconductor device 8 is a P-type transistor, the source/drain 261 may include a compressive stress material. For example, the compressive stress material may be a material having a larger lattice constant than silicon (Si) such as, for example, SiGe. The compressive stress material may improve the mobility of carriers in a channel region by applying a compressive stress to the fin F1.

The gate of the N-type transistor in FIGS. 1 and 2 and the gate of the P-type transistor in FIGS. 4, 5 and 6 may be applied to a fin-type transistor.

That is, when the gate of the N-type transistor in FIGS. 1 and 2 is applied to a fin-type transistor, the source/drain may be made of the same material as the substrate or include a tensile stress material. For example, when the substrate is made of Si, the source/drain may be made of Si or a material having a smaller lattice constant than Si (for example, SiC).

The P-type work function regulating film 250 may be, for example, a TiN film, but aspects of the present inventive concept are not limited thereto. The P-type work function regulating film 250 may have a thickness in range of about 50 Å to about 100 Å.

The N-type work function regulating film 270 may be made of a material selected from the group consisting of TiAl, TiAlN, TaC, TiC, and HfSi. For example, the N-type work function regulating film 27Q may be a TiAl film. The N-type work function regulating film 270 may have a thickness in range of about 30 Å to about 120 Å.

The second adhesive film 280 may include a TiN film and a Ti film sequentially stacked. For example, the TiN film may have a thickness in range of about 5 Å to about 100 Å and the Ti film may have a thickness in range of about 5 Å to about 100 Å.

The second cobalt film 260 may be formed to have a thickness of, for example, in range of about 5 to about 50 Å.

For example, the second etch stopper film 240 may include at least one of TiN and TaN. In addition, the second etch stopper film 240 may include a TiN film and a TaN film sequentially stacked.

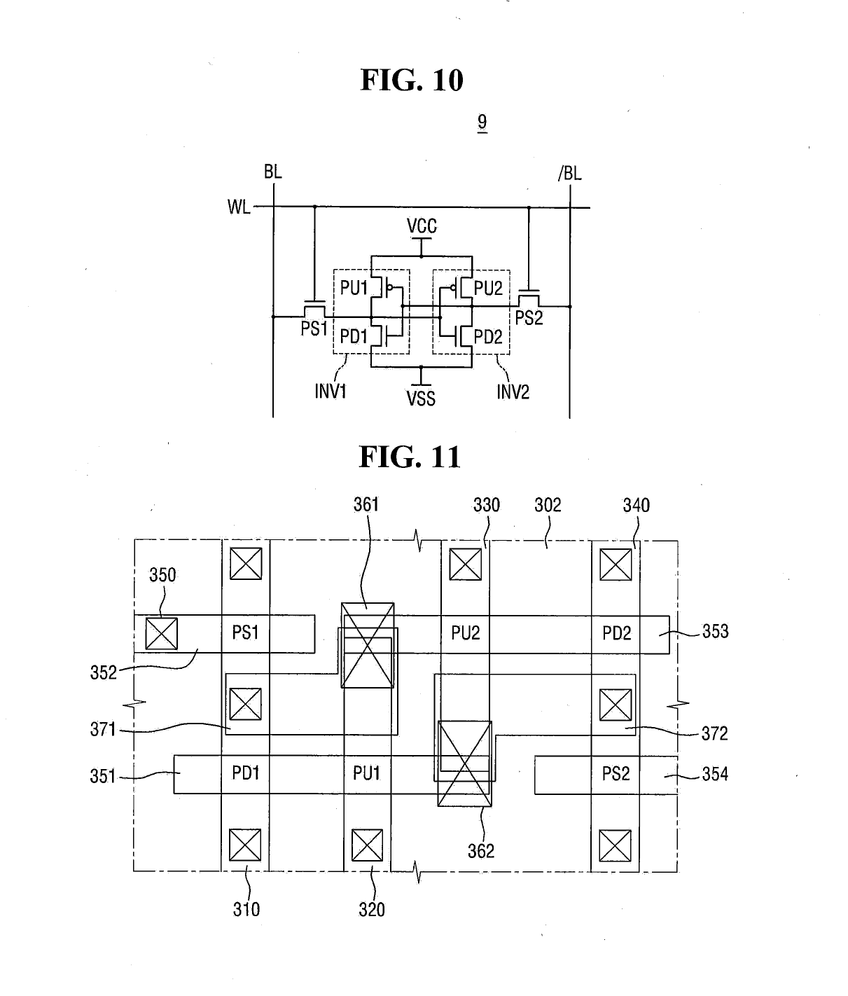

FIGS. 10 and 11 are circuit diagram and a layout view illustrating the semiconductor device according to some embodiments of the present inventive concept.

The semiconductor device 9 may include a pair of inverters INV1 and INV2 connected in parallel between a power supply node Vcc and a ground node Vss, and a first pass transistor PS1 and a second pass transistor PS2 connected to output nodes of the respective inverters INV1 and INV2. The first pass transistor PS1 and the second pass transistor PS2 may be connected to a bit line BL and a complementary bit line BL/, respectively. Gates of the first pass transistor PS1 and the second pass transistor PS2 may be connected to a word line WL.

The first inverter INV1 includes a first pull-up transistor PU1 and a first pull-down transistor PD1 connected in series, and the second inverter INV2 includes a second pull-up transistor PU2 and a second pull-down transistor PD2 connected in series. The first pull-up transistor PU1 and the second pull-up transistor PU2 may be PMOS transistors, and the first pull-down transistor PD1 and the second pull-down transistor PD2 may be NMOS transistors.

In addition, in order to a constitute a latch circuit by the first inverter INV1 and the second inverter INV2, an input node of the first inverter INV1 is connected to an output node of the second inverter INV2, and an input node of the second inverter INV2 is connected to an output node of the first inverter INV1.

A first active region 310, a second active region 320, a third active region 330, and a fourth active region 340, spaced apart from each other, are formed to extend lengthwise in one direction (e.g., in a vertical direction of FIG. 11). The second active region 320 and the third active region 330 may extend in a shorter length than the first active region 310 and the fourth active region 340.

In addition, a first gate electrode 351, a second gate electrode 352, a third gate electrode 353, and a fourth gate electrode 354 extend lengthwise in the other direction (e.g., in a horizontal direction of FIG. 11) and are formed to cross the first to fourth active regions 310-340. In detail, the first gate electrode 351 may entirely cross over the first active region 310 and the second active region 320 while partially overlapping a terminal end of the third active region 330. The third gate electrode 353 may entirely cross over the fourth active region 340 and the third active region 330 while partially overlapping a terminal end of the second active region 320. The second gate electrode 352 and the fourth gate electrode 354 are formed to cross over the first active region 310 and the fourth active region 340, respectively.

The first pull-up transistor PU1 is defined at a region around an intersection of the first gate electrode 351 and a second fin F2, the first pull-down transistor PD1 is defined at a region around an intersection of the first gate electrode 351 and the first fin F1, and the first pass transistor PS1 is defined at a region around an intersection of the second gate electrode 352 and the first fin F1. The second pull-up transistor PU2 is defined at a region around an intersection of the third gate electrode 353 and the third active region 330, the second pull-down transistor PD2 is defined at a region around an intersection of the third gate electrode 353 and the fourth active region 340, and the second pass transistor PS2 is defined at a region around an intersection of the fourth gate electrode 354 and the fourth active region 340.

The source/drain may be formed at both sides of the intersections of the first to fourth gate electrodes 351-354 and the first to fourth fins 310, 320, 330 and 340.

In addition, a plurality of contacts 350 may be formed.

A shared contact 361 simultaneously connects the second active region 320, the third gate electrode 353, and a wire 371 to one another. A shared contact 362 simultaneously connects the third active region 330, the first gate electrode 351 and a wire 372 to one another.

For example, the first pull-up transistor PU1 and the second pull-up transistor PU2 may include at least one of the structures in FIGS. 3 through 6, and the first pull-down transistor PD1, the first pass transistor PS1, the second pull-down transistor PD2, and the second pass transistor PS2 may include at least one of the structures described in FIGS. 1 and 2.

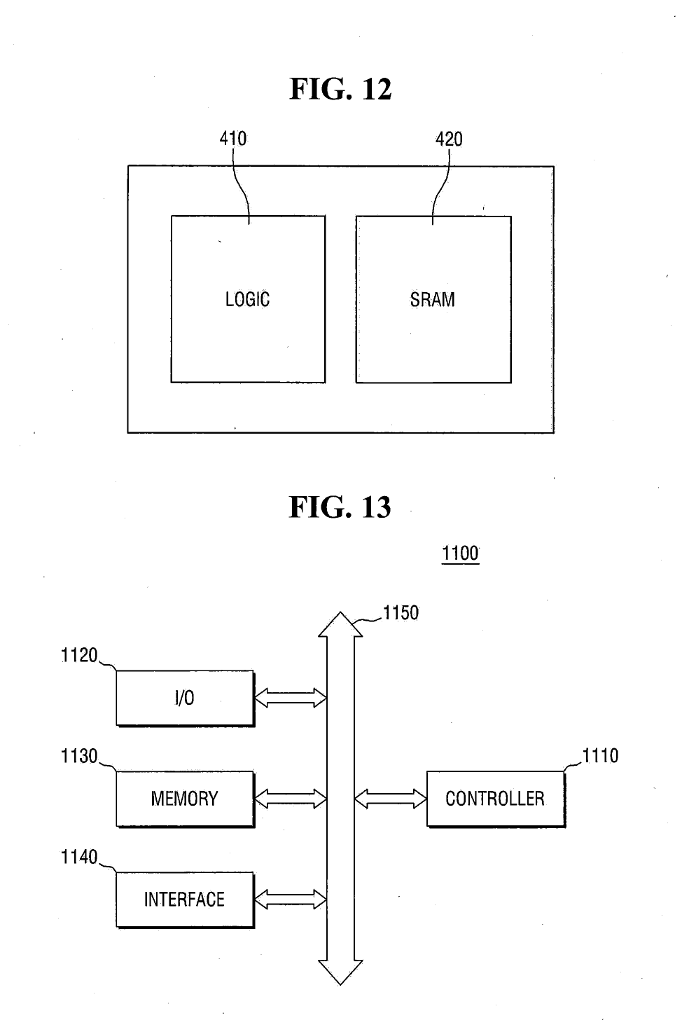

Referring to FIG. 12, the semiconductor device according to some embodiments of the present inventive concept may include a logic region 410 and an SRAM region 420.

The gate of the transistors according some embodiments may be applied to the logic region 410 but not applied to the SRAM region 420.

In some embodiments, gate of the transistors according some embodiments may be applied to both of the logic region 410 and the SRAM region 420.

The gate of the transistors according some embodiments may be applied to the SRAM region 420 but not applied to the logic region 410.

The logic region 410 and the SRAM region 420 are illustrated in FIG. 12 as an example, but aspects of the present inventive concept are not limited thereto. The present inventive concept may also be applied to a memory region different from the logic region 410 (e.g., DRAM, MRAM, RRAM, or PRAM).

FIG. 13 is a block diagram of an electronic system incorporating a semiconductor device according to some embodiments of the present inventive concept.

Referring to FIG. 13, the electronic system 1100 according to some embodiments of the present inventive concept may include a controller 1110, an input/output (I/O) device 1120, a memory device 1130, an interface 1140 and a bus 1150. The controller 1110, the I/O device 1120, the memory device 1130 and/or the interface 1140 may be connected to each other through the bus 1150. The bus 1150 may corresponds to a path through which data moves.

The controller 1110 may include at least one of a microprocessor, a digital signal processor, a microcontroller, and logic devices capable of performing similar functions to those performed by these devices. The I/O device 1120 may include a keypad, a keyboard, a display device, and the like. The memory device 1130 may store data and/or instructions. The interface 1140 may transmit/receive data to/from a communication network. The interface 1140 may be wired or wireless. For example, the interface 1140 may include an antenna or a wired/wireless transceiver. The electronic system 1100 may be used as an operating memory for improving the operation of the controller 1110 and may further include a high-speed DRAM and/or SRAM. The gate of the transistor according to some embodiments of the present inventive concept may be in the memory device 1130 or may be used as a component of the controller 1110 or the I/O device 1120.

The electronic system 1100 may be applied to a personal digital assistant (PDA) a portable computer, a web tablet, a wireless phone, mobile phone, a digital music player, a memory card, and all electronic products capable of transmitting and/or receiving information in a wireless environment.

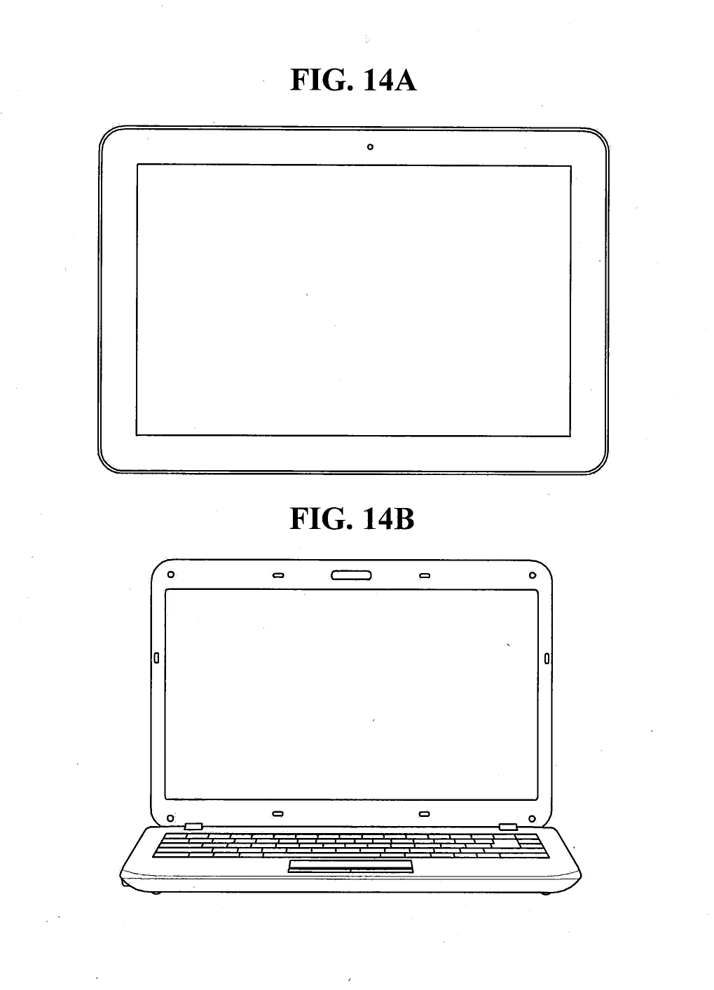

FIGS. 14A and 14B illustrate exemplary electronic systems including a semiconductor device according to some embodiments of the present inventive concept. FIG. 14A illustrates a tablet PC and FIG. 14B illustrates a notebook computer. At least one of the semiconductor devices 1 to 9 according to some embodiments of the present inventive concept may be used in a tablet PC, a notebook computer, or the like. The semiconductor device according to some embodiments of the present inventive concept can be applied to other integrated circuit devices and/or electronic systems.

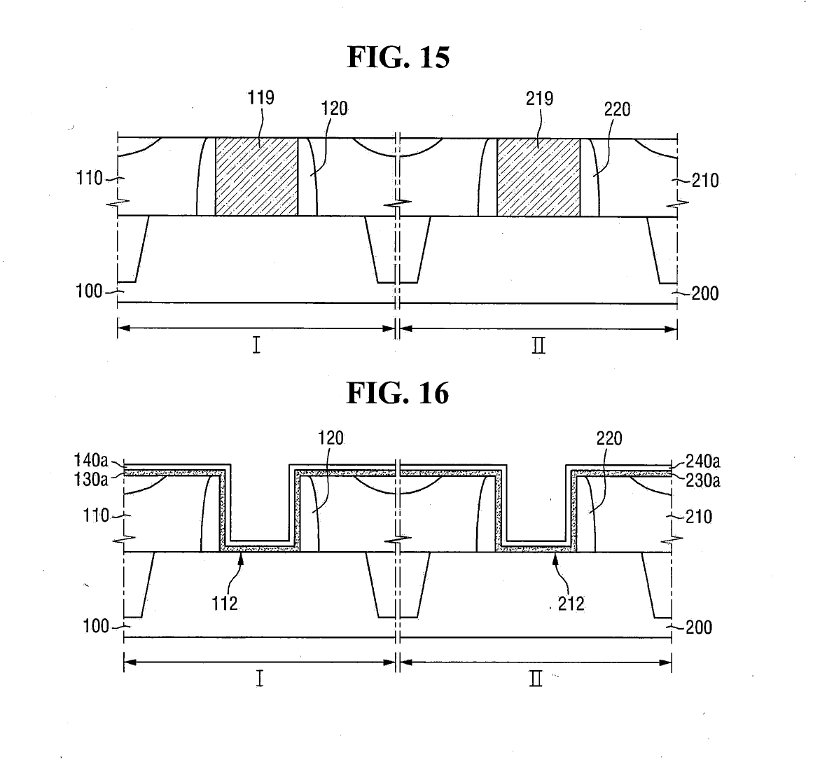

Hereinafter, a manufacturing method of the semiconductor device according to some embodiments of the present inventive concept will be described with reference to FIGS. 15 through 21 with FIG. 7. FIGS. 15 to 21 illustrate intermediate process steps for explaining the manufacturing method of the semiconductor device according to some embodiments of the present inventive concept.

Referring to FIG. 15, a substrate 100 including a first region I and a second region II is provided.

A first sacrificial gate pattern 119 may be formed in the first region I, and a spacer 120 may be formed at sidewalls of the first sacrificial gate pattern 119. The first interlayer dielectric film 110 may surround the first sacrificial gate pattern 119 and the spacer 120 exposing a top surface of the first sacrificial gate pattern 119.

A second sacrificial gate pattern 219 may be formed in the second region II and a spacer 220 may be formed at sidewalls of the second sacrificial gate pattern 219. The second interlayer dielectric film 210 may surround the second sacrificial gate pattern 219 and the spacer 220 exposing a top surface of the second sacrificial gate pattern 219.

The first sacrificial gate pattern 119 and the second sacrificial gate pattern 219 may be made of, for example, polysilicon, but aspects of the present inventive concept are not limited thereto.

Referring to FIG. 16, the first sacrificial gate pattern 119 and the second sacrificial gate pattern 219 are removed to form a first trench 112 in the first region I in the first interlayer dielectric film 110 and a second trench 212 in the second region II in the second interlayer dielectric film 210.

A first gate insulating film 130a may be formed in the first trench 112 and a second gate insulating film 230a may be formed in the second trench 212. The first gate insulating film 130a may be conformally formed along the top surface of the first interlayer dielectric film 110 and the sidewalls and bottom surface of the first trench 112. The second gate insulating film 230a may be conformally formed along the top surface of the second interlayer dielectric film 210 and the sidewalls and bottom surface of the second trench 212. The first gate insulating film 130a and the second gate insulating film 230a may include high-k dielectric films.

A first etch stopper film 140a may be formed on the first gate insulating film 130a in the first trench 112, and a second etch stopper film 240a may be formed on the second gate insulating film 230a in the second trench 212. The first etch stopper film 140a and the second etch stopper film 240a may also be formed on the first interlayer dielectric film 110a and the second interlayer dielectric film 210a, respectively.

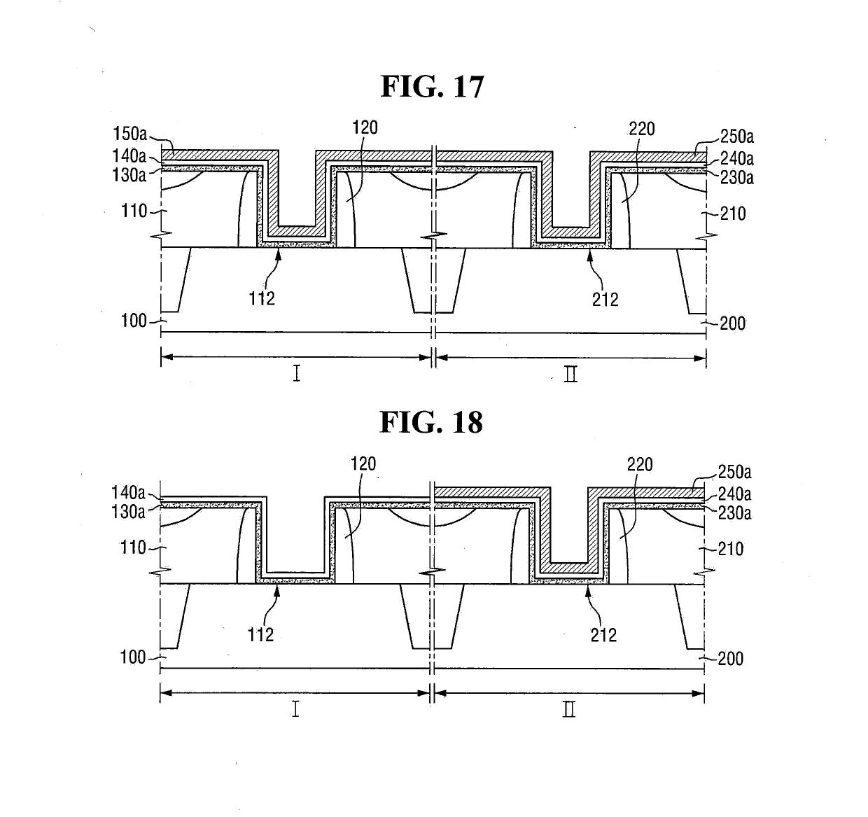

Referring to FIG. 17, P-type work function regulating films 150a and 250a are formed on the first etch stopper film 140a and the second etch stopper film 240a, respectively.

As shown, the P-type work function regulating films 150a and 250a may be conformally formed on the top surface of the first interlayer dielectric film 110 and the sidewalls and bottom surface of the first trench 112 and on the top surface of the second interlayer dielectric film 210 and the sidewalls and bottom surface of the second trench 212, respectively.

The P-type work function regulating films 150a and 250a may include such as, for example, TiN.

Referring to FIG. 18, the P-type work function regulating film 150a formed in the first region I may be removed while leaving the P-type work function regulating film 250a formed in the second region II. That is, the P-type work function regulating film 250a may be left on the second gate insulating film 230a in the second trench 212.

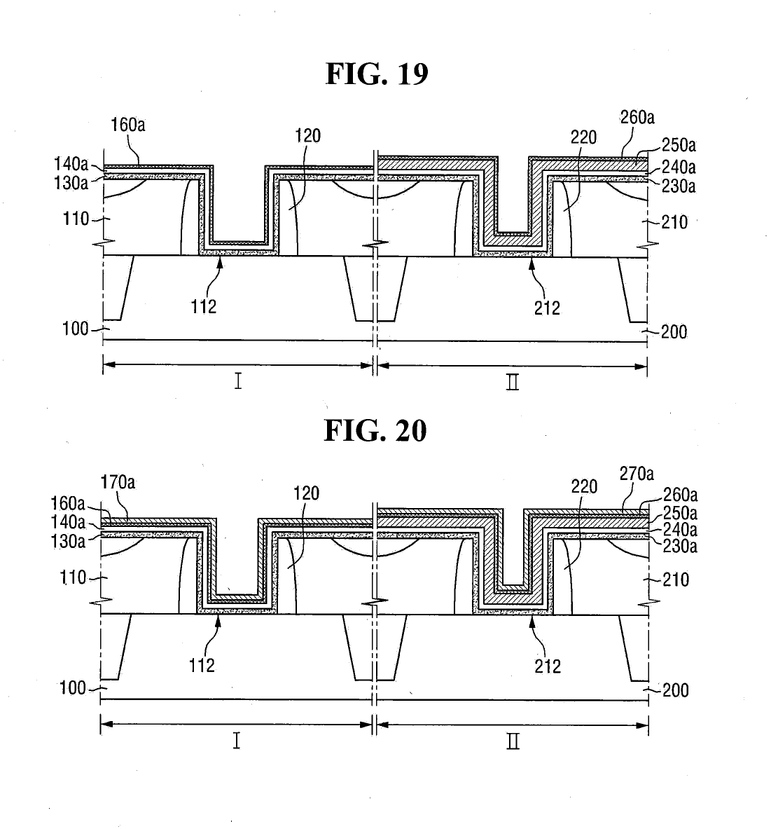

Referring to FIG. 19, a first cobalt film 160a is formed on the first gate insulating film 130 in the first trench 112, and a second cobalt film 260a is formed on the P-type work function regulating film 250a in the second trench 212.

The first cobalt film 160a and the second cobalt film 260a may be formed by CVD or ALD to conformally forming the first cobalt film 160a and the second cobalt film 260a with appropriate thicknesses.

Referring to FIG. 20, a N-type work function regulating film 170a is formed on the first cobalt film 160a in the first trench 112, and a N-type work function regulating film 270a is formed on the second cobalt film 260a in the second trench 212.

The N-type work function regulating films 170a and 270a may be conformally formed on the top surface of the first interlayer dielectric film 110 and the sidewalls and bottom surface of the first trench 112 and on the top surface of the second interlayer dielectric film 210 and the sidewalls and bottom surface of the second trench 212, respectively.

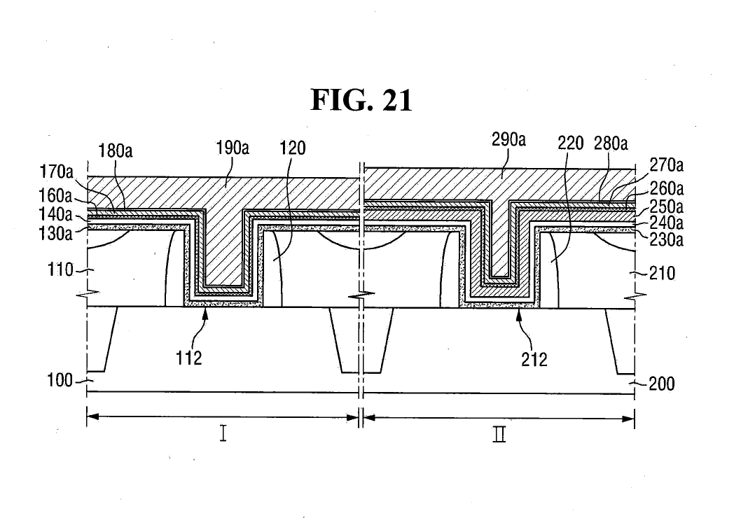

Referring to FIG. 21, a first adhesive film 180a may be formed on the N-type work function regulating film 170a in the first trench 112, and a second adhesive film 280a may be formed on the N-type work function regulating film 270a in the second trench 212.

A first metal gate pattern 190a is formed on the first adhesive film 180a in the first trench 112 to fill the first trench 112, and the second metal gate pattern 290a is formed on the second adhesive film 280a in the second trench 212 to fill the second trench 212.

Referring back to FIG. 7, a planarization process is performed to expose the top surface of the first interlayer dielectric film 110 and the top surface of the second interlayer dielectric film 210. Through the planarization process, a first replacement metal gate of an N-type transistor may be formed in the first region I, and a second replacement metal gate of a P-type transistor may be formed in the second region II.

That is to say, the first replacement metal gate may include the N-type work function regulating film 170 and the first cobalt film 160 disposed under the first work function regulating film. Alternatively, the first replacement metal gate may not include a P-type work function regulating film. The second replacement metal gate may include the second cobalt film 260 disposed between the P-type work function regulating film 250 and N-type work function regulating film 270.

The above-disclosed subject matter is to be considered illustrative, and not restrictive, and the appended claims are intended to cover all such modifications, enhancements, and other embodiments, which fall within the true spirit and scope. Thus, to the maximum extent allowed by law, the scope is to be determined by the broadest permissible interpretation of the following claims and their equivalents, and shall not be restricted or limited by the foregoing detailed description.

What is claimed is:

1. A transistor of a first conductivity type, comprising:
an interlayer dielectric film including a trench on a substrate;
a gate insulating film on sidewalls and a bottom surface of the trench;
an etch stopper film on the gate insulating film;
a work function regulating film of the first conductivity type on the etch stopper film;
a metal gate pattern on the work function regulating film filling the trench; and
a cobalt film between the etch stopper film and the work function regulating film.

2. The transistor of claim 1, wherein the first conductivity type is P-type.

3. The transistor of claim 2, further comprising an N-type work function regulating film between the work function regulating film and the metal gate pattern.

4. The transistor of claim 1, wherein the etch stopper film comprises a TiN film and a TaN film sequentially stacked between the gate insulating film and the work function regulating film, and wherein the cobalt film is between the TiN film and the TaN film.

5. An integrated circuit device including a first transistor of a first conductivity type, the first transistor comprising:
a first gate insulating layer on a substrate;
an etch stopper layer on the first gate insulating layer;
a work function regulating layer of the first conductivity type on the etch stopper layer;
a first metal gate layer on the work function regulating layer; and
a first diffusion barrier layer between the first gate insulating layer and the work function regulating layer.

6. The integrated circuit device of claim 5, wherein the first diffusion barrier layer comprises a cobalt film.

7. The integrated circuit device of claim 6, wherein the etch stopper layer comprises a TiN film and a TaN film, and the first diffusion barrier layer is between the TiN film and the TaN film.

8. The integrated circuit device of claim 5, wherein the work function regulating layer of the first conductivity type comprises a first work function regulating layer, and the first transistor further comprises a second work function regulating layer of a second conductivity type on the first work function regulating layer.

9. The integrated circuit device of claim 8, wherein the first diffusion barrier layer comprises a cobalt film.
